(19) United States
(12) Patent Application Publication
(10) Pub. No.: US 2016/0276179 A1
(43) Pub. Date: Sep. 22, 2016

(54) NITROGEN OXIDE ABATEMENT IN SEMICONDUCTOR FABRICATION

(71) Applicant: Applied Materials, Inc., Santa Clara, CA (US)

(72) Inventors: Paul E. Fisher, Los Altos, CA (US); Monique McIntosh, San Jose, CA (US); Andrew Herbert, Lake Oswego, OR (US); Colin John Dickinson, San Jose, CA (US)

(21) Appl. No.: 14/418,411

(22) PCT Filed: Dec. 18, 2014
(86) PCT No.: PCT/US2014/071168

§ 371 Date: Jan. 29, 2015

Related U.S. Application Data
(60) Provisional application No. 61/968,198, filed on Mar. 20, 2014.
(60) Provisional application No. 61/927,272, filed on Jan. 14, 2014.

(51) Int. Cl. H01L 21/67; B01D 53/76; B01D 53/34; B01D 53/56

(52) U.S. Cl. CPC H01L 21/67017; B01D 53/56; B01D 53/76; B01D 53/346

(57) ABSTRACT

Embodiments enclosed herein relate to methods and apparatus for reducing nitrogen oxides (NOₓ) produced during processing, such as during semiconductor fabrication processing. A processing system may include an abatement controller and an effluent abatement system, wherein the abatement controller controls the effluent abatement system to reduce NOₓ production, while ensuring abatement of the effluent gases from the processing system. The effluent abatement system may include a combustion-type effluent abatement system and/or a plasma-type effluent abatement system. The abatement controller may select operating modes of the effluent abatement systems to reduce NOₓ production.

### BACKGROUND OF THE INVENTION

1. Field of the Invention

Embodiments of the present disclosure generally relate to semiconductor processing equipment. More particularly, embodiments of the present disclosure relate to techniques for reducing nitrogen oxides (NOₓ) produced during semiconductor fabrication.

2. Description of the Related Art

NOₓ emissions are of increasing importance to the semiconductor processing industry, particularly as fabricators move to processing 450 mm wafers. The increased wafer size leads to increases in the flows of the processing gases required for processing, which in turn leads to increases in the NOₓ emissions from the processing. Semiconductor processing facilities have regulatory limits on total NOₓ emissions, and the increased NOₓ emissions have the potential to cause the facilities to reach or exceed their regulatory limits.

The process gases used by semiconductor processing facilities include many compounds which must be abated or treated before disposal, due to regulatory requirements and environmental concerns. Among these compounds are perfluorocompounds (PFCs). The current technology for abatement of the PFCs and other process chemicals involves burning them. However, burning of these materials results in the generation of NOₓ, due to combustion of the process chemicals and the reaction of nitrogen and oxygen present in the air used in the combustion. Thus, the increases in the flows of processing gases mentioned above lead to increases in the generation of NOₓ by semiconductor processing facilities.

There is a need, therefore, for techniques that reduce NOx emissions from abating PFCs and other process chemicals from semiconductor processing facilities, compared to current abatement technologies.

### SUMMARY OF THE INVENTION

A method for reducing nitrogen oxides (NOₓ) produced by a processing system including an effluent abatement system is provided. The method generally includes obtaining at least one operating parameter of the processing system and selecting an operating mode of the effluent abatement system, based at least on the obtained one operating parameter.

In another embodiment, a method for reducing nitrogen oxides (NOₓ) produced by a processing system including a combustion-type effluent abatement system is provided. The method generally includes making a determination whether to abate effluent by combusting the effluent, exposing the effluent to a plasma, both, or neither; operating the combustion-type effluent abatement system according to the determination; and operating a plasma-type effluent abatement system according to the determination.

In another embodiment, a system for reducing nitrogen oxides (NOₓ) produced by a processing system including an effluent abatement system is provided. The nitrogen oxide reducing system generally includes a controller configured to obtain at least one operating parameter of the processing system and select an operating mode of the effluent abatement system from a group of at least three operating modes, based at least on the obtained one operating parameter.

In another embodiment, a system for reducing nitrogen oxides (NOₓ) produced by a processing system is provided. The nitrogen oxide reducing system generally includes a controller operable to make a determination whether to abate effluent by combusting the effluent, exposing the effluent to a plasma, both, or neither; and a controller operable to control operation of a combustion-type effluent abatement system and a plasma-type effluent abatement system according to the determination.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of an exemplary processing system, according to one embodiment of the present disclosure.

FIGS. 2A and 2B are a schematic illustrations of exemplary processing systems, according to embodiments of the present disclosure.

FIG. 3 is a schematic illustration of an exemplary processing system, according to one embodiment of the present disclosure.

FIG. 4 sets forth an exemplary operation that may be performed by a processing system, in accordance with certain aspects of the present disclosure.

FIG. 5 sets forth an exemplary operation that may be performed by a processing system, in accordance with certain aspects of the present disclosure.

### DETAILED DESCRIPTION

A control system and methods for reducing NOₓ production from a processing system are provided. The control system reduces the production of NOₓ from an effluent abatement system of the processing system. For example, the control system described herein controls a combustion-type effluent abatement system to minimize NOₓ production in the effluent abatement system while ensuring adequate abatement of chemicals in the effluent. The control system may also control a plasma-type effluent abatement system to minimize NOₓ production in the effluent abatement system while ensuring adequate abatement of chemicals in the effluent.

One embodiment disclosed herein selects an operating mode of an effluent abatement system from a group of operating modes, based on at least one operating parameter of a processing system. For example, in one aspect, the effluent abatement system is operated in a first, minimum capacity mode. On initiation of gas flow into the processing system, in response thereto, the effluent abatement system is operated in a second, maximum capacity mode. The second mode can be operating the effluent abatement system to achieve a particular temperature, for example.

Another embodiment, which is not strictly related to the first, makes a determination whether to abate effluent from a processing system by combusting the effluent, exposing the effluent to a plasma, both combusting the effluent and exposing the effluent to a plasma, or neither combusting the effluent nor exposing the effluent to a plasma, and operates a combustion-type effluent abatement system and a plasma-type effluent abatement system according to the determination.

As used herein, “abate” means to reduce, but not necessarily eliminate. That is, as used herein, effluent is abated by reducing the concentration of certain components in effluent. Similarly, an “effluent abatement system” reduces the concentration of certain components in effluent.

As used herein “nitrogen oxides” is a generic term for oxides of nitrogen. The term as used herein specifically includes nitric oxide NO and nitrogen dioxide NO₂.

In semiconductor processing, process gases typically react with a substrate within a processing chamber, forming byproduct gases. The byproduct gases and unreacted process gases together make up effluent gases that are removed (e.g., pumped) from the processing chamber. While embodiments of the present disclosure are described with reference to an exemplary semiconductor processing system, the disclosure is not so limited, and is applicable to any processing or manufacturing system producing effluent gases requiring abatement.

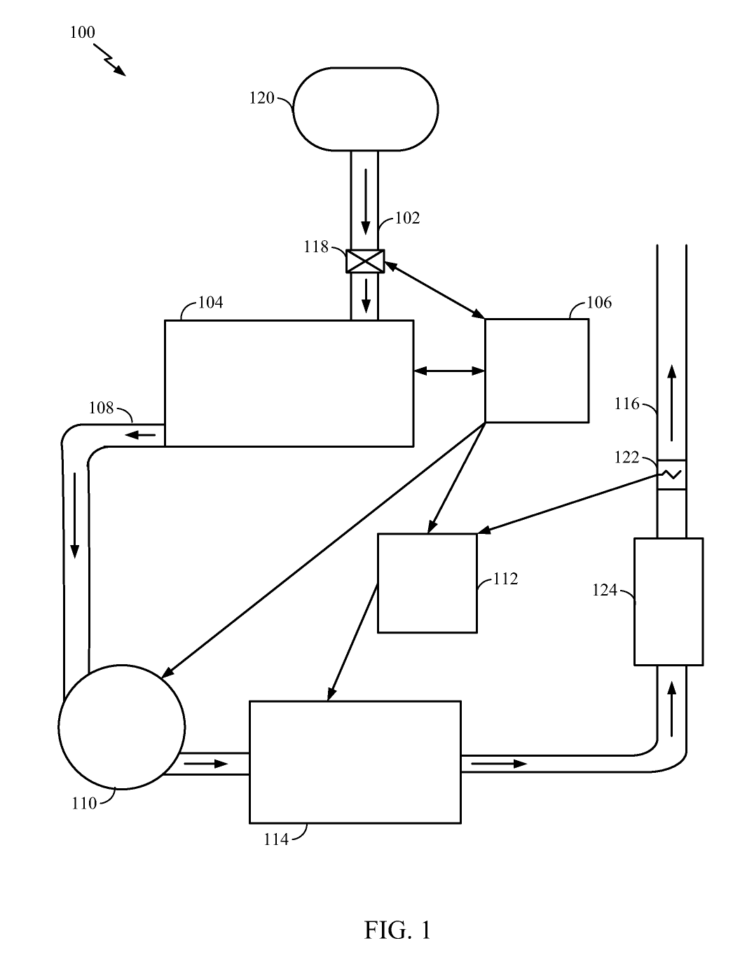

FIG. 1 is a schematic diagram of a processing system 100, according to embodiments of the present disclosure. The processing system 100 generally includes one or more process gas sources 120, one or more valves 118, a processing chamber 104, a process controller 106, a vacuum pump 110, an abatement controller 112, an effluent disposal or abatement subsystem 114, an optional scrubber 124, one or more optional exhaust gas sensors 122, and an exhaust 116. The process controller 106 and the abatement controller 112 may be the same controller in some embodiments of the present disclosure.

Referring to FIG. 1, process gases are supplied from a process gas source 120 (e.g., a storage tank or pipeline) via an inlet 102 to the processing chamber 104. The supply of process gases is controlled and monitored by the process controller 106, which may control, for example, one or more valves 118. The process controller 106 may comprise a computer, for example. The process controller 106 controls and monitors operations in the processing chamber 104. For example, the process controller 106 may control heating elements (not shown) to control the temperature within the processing chamber 104 and robots (not shown) to control the movement of materials within the processing chamber 104. Effluent gases exit the processing chamber 104 via one or more outlets 108. The effluent gases are pumped out of the processing chamber 104 by the vacuum pump 110. The vacuum pump 110 may be controlled by the process controller 106, for example, to maintain pressure in the processing chamber 104 within a desired range.

Still referring to FIG. 1, the abatement controller 112 obtains process parameters (for example, inlet gas composition, gas flow rate, pumping rate, processing temperature, etc.) from the process controller 106. The abatement controller 112 may comprise a computer. The abatement controller 112 controls operations of the effluent abatement system 114. The effluent abatement system 114 may typically comprise a combustion-type effluent abatement system, such as an Atlas TPU™ effluent abatement system available from Edwards Vacuum™. The abatement controller 112 may, for example, control the effluent abatement system 114 to operate with a high or a low flow rate of combustion gas. The abated effluent gases may then flow to an optional scrubber 124 for removal of particulates, for example, or directly to an exhaust 116, if operations and regulatory requirements allow. The abatement controller 112 may select an operating mode for the effluent abatement system 114 from a group including a high capacity mode, a low capacity mode, and an idle mode. The high capacity mode involves a high flow rate of combustion gas (e.g., propane, natural gas, etc.) and air into a combustion-type effluent abatement system, and may be selected while active processing is occurring in the processing system. By selecting the high capacity mode, the abatement controller 112 can ensure adequate abatement of the effluent gases produced. The low capacity mode involves a lower flow rate of combustion gas and air into a combustion-type effluent abatement system, and may be selected when active processing is not occurring, but has finished recently or is expected to start soon (e.g., when processing of a substrate is completed and a new substrate is being placed in the processing chamber). By selecting the low capacity mode, the abatement controller 112 can ensure adequate abatement of residual effluent gases, while reducing NOₓ production in the effluent abatement system. The idle mode involves the lowest flow rate of combustion gas and air into a combustion-type effluent abatement system, and possibly no flow at all (i.e., the effluent disposal system is off). The idle mode may be selected when there is no active processing occurring, or when the process performed in the processing chamber 104 uses process gases and produces effluent gases that do not require combustion-type abatement. By selecting the idle mode, the abatement controller 112 can achieve a maximum reduction in NOₓ production in the effluent abatement system. The abatement controller 112 may be referred to as a nitrogen oxide reducing system, when configured as described herein.

According to certain aspects of the present disclosure, the abatement controller 112 may select a high capacity mode for the effluent abatement system 114, if the abatement controller 112 cannot obtain an operating parameter. This aspect is a “fail-safe” feature, in that by selecting high capacity mode, the abatement controller 112 ensures that effluent abatement regulatory requirements are met when operating parameters cannot be obtained, such as in the event of a communications failure between the abatement controller 112 and the process controller 106.

According to certain aspects of the present disclosure, the abatement controller 112 may select an operating mode for the effluent abatement system 114 from a group including at least one of a high combustion gas flow rate mode, a low combustion gas flow rate mode, a high combustion temperature mode, a low combustion temperature mode, a high combustion air flow rate mode, and a low combustion air flow rate mode.

In the high combustion gas flow rate mode, the abatement controller 112 controls the effluent abatement system 114 to use combustion gas at a high rate. This mode may be selected, for example, when the effluent comprises chemicals requiring abatement by a reduction reaction and a high combustion gas flow rate promotes that reduction reaction.

In the low combustion gas flow rate mode, the abatement controller 112 controls the effluent abatement system 114 to use combustion gas at a low rate. This mode may be selected, for example, when the effluent comprises chemicals requiring abatement by oxidation.

In the high combustion temperature mode, the abatement controller 112 controls the effluent abatement system 114 to use combustion gas and air in quantities and proportions which will result in a high combustion temperature. This mode may be selected, for example, when the effluent comprises chemicals which are resistant to low-temperature combustion.

In the low combustion temperature mode, the abatement controller 112 controls the effluent abatement system 114 to use combustion gas and air in quantities and proportions resulting in a low combustion temperature. This mode may be selected, for example, when the effluent does not comprise chemicals resistant to low-temperature combustion. NOₓ production in the effluent abatement system 114 in the low combustion temperature mode may be reduced, compared to other modes.

In the high combustion air flow rate mode, the abatement controller 112 controls the effluent abatement system 114 to use combustion air at a high rate. This mode may be selected, for example, when the effluent comprises chemicals requiring abatement by oxidation.

In the low combustion air flow rate mode, the abatement controller 112 controls the effluent abatement system 114 to use combustion air at a low rate. This mode may be selected, for example, when the effluent comprises chemicals requiring abatement by a reduction reaction.

Two or more modes may be simultaneously selected by the abatement controller 112, if the two modes are not mutually exclusive (e.g., the abatement controller 112 may not simultaneously select the high combustion gas flow rate mode and the low combustion gas flow rate mode).

According to certain aspects of this disclosure, the abatement controller 112 may control a supply of reducing reagents (e.g., hydrogen or ammonia) to the effluent abatement system. The reducing reagents may reductively react with NOₓ in the effluent gases, further reducing the concentration of NOₓ in the effluent gases.

According to certain aspects of the present disclosure, the abatement controller 112 may obtain an indication of NOₓ in the exhaust 116 of the effluent disposal system and select an operating mode of the effluent abatement system 114 based further on the obtained indication. The indication may be obtained, for example, from a sensor 122 in the exhaust 116 which determines a concentration of NOₓ in the exhaust gases. For example, the abatement controller 112 may control the effluent abatement system 114 to operate at a lower temperature, if the indication indicates high NOₓ concentration in the exhaust 116.

According to certain aspects of the present disclosure, the abatement controller 112 may adjust a combustion gas flow rate or combustion air flow rate into the effluent disposal system without changing an operating mode of the effluent disposal system, in order to reduce NOₓ production in the effluent disposal system. The abatement controller 112 may adjust the combustion gas flow rate, combustion air flow rate, or both flow rates into the effluent disposal system based on process parameters obtained from the process controller 106 or based on an indication of NOₓ in the exhaust 116 of the effluent disposal system.

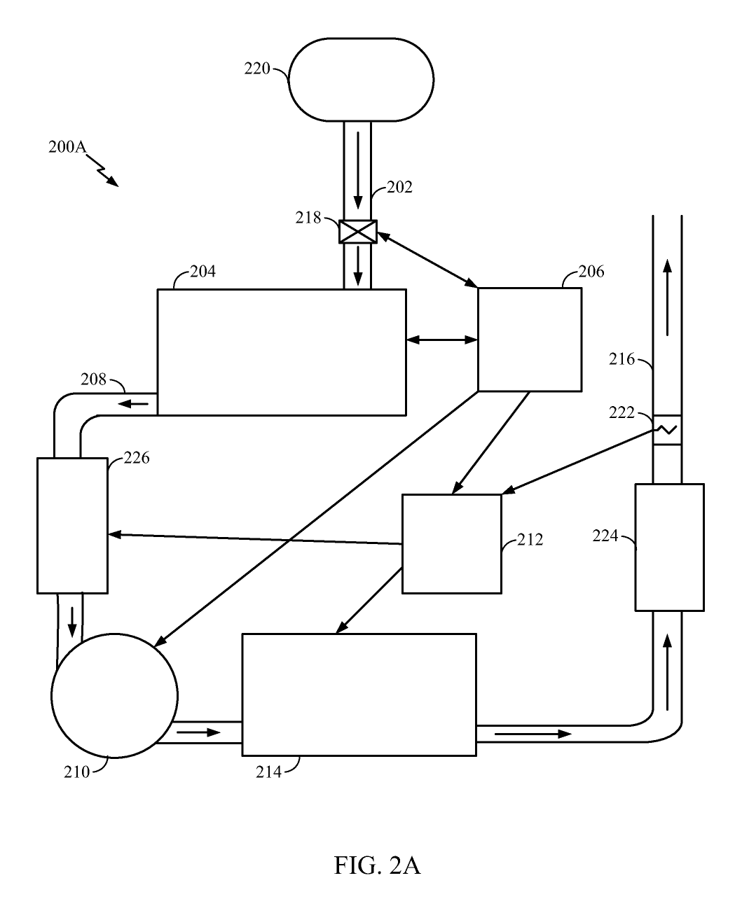

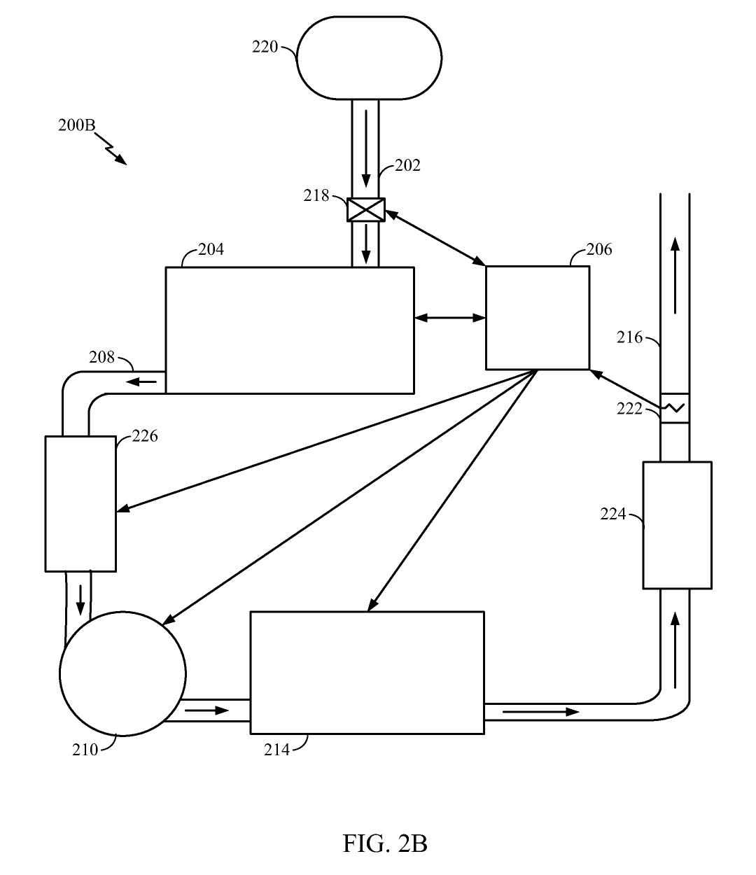

FIG. 2A is a schematic diagram of a processing system 200A, according to embodiments of the present disclosure. The processing system 200A shown in FIG. 2A is similar to the processing system 100 shown in FIG. 1, with many similar components. The processing system 200A generally includes one or more process gas sources 220, one or more valves 218, a processing chamber 204, a process controller 206, a vacuum pump 210, an abatement controller 212, a combustion-type effluent disposal or abatement subsystem 214 downstream from the vacuum pump 210, a plasma-type effluent disposal or abatement subsystem 226, such as a ZFP2™ effluent abatement system, available from Applied Materials™, upstream from the vacuum pump 210, an optional scrubber 224, one or more optional exhaust gas sensors 222, and an exhaust 216. The process controller 206 and the abatement controller 212 may be the same controller, in some embodiments of the present disclosure. FIG. 2B shows a schematic diagram of a processing system 200B, according to embodiments of the present disclosure. The processing system 200B is identical to the processing system 200A, except a process controller 206 also acts as an abatement controller in FIG. 2B, rather than there being a separate abatement controller, as in processing system 200A.

Referring to FIG. 2A, process gases are supplied from a process gas source 220 via an inlet 202 to the processing chamber 204. The supply of process gases is controlled and monitored by the process controller 206 which may control, for example, one or more valves 218. The process controller 206 may comprise a computer, for example. The process controller 206 controls and monitors operations in the processing chamber 204. Effluent gases exit the processing chamber 204 via one or more outlets 208.

Still referring to FIG. 2A, the effluent gases then flow to a plasma-type effluent abatement system 226. The plasma-type effluent abatement system 226 may abate the effluent gases by exposing them to a plasma. The plasma-type effluent abatement system 226 may generate a plasma to abate the effluent gases by various techniques, including radio frequency (RF), direct current (DC), or microwave (MW) based power discharge techniques. The plasma-type effluent abatement system 226 may operate in an “always-on” mode, operate in an operational mode selected by the abatement controller 212, or cease operations if the abatement controller 212 directs it to turn off. The abatement controller 212 selects operational modes for the plasma-type effluent abatement system based on process parameters obtained from the process controller 206 and/or an indication of NOₓ in the exhaust 216 of the processing system.

Referring to FIG. 2A, the effluent gases are then pumped out of the plasma-type effluent abatement system 226 by the vacuum pump 210. The vacuum pump 210 may be controlled by the process controller 206. Similar to as described above with reference to FIG. 1, the abatement controller 212, which may be a computer, special processor, etc., obtains process parameters (for example, inlet gas composition, flow rate, pumping rate, processing temperature, etc.) from the process controller 206. Additionally, the abatement controller may obtain an indication of NOₓ in the exhaust 216 from one or more optional sensors 222. The abatement controller 212 controls operations of the combustion-type effluent abatement system 214, as well as the plasma-type effluent abatement system. The combustion-type effluent abatement system 214 may abate the effluent gases by combusting them with a mixture of combustion gas (e.g., natural gas, propane, etc.) and air. The abatement controller 212 may control the combustion-type effluent abatement system 214 by selecting from several modes of operation similar to those described above with reference to FIG. 1, including a mode wherein the combustion-type effluent abatement system ceases combustion operations. The abatement controller 212 may be referred to as a nitrogen oxide reducing system, when configured as described herein.

Referring to FIG. 2B, the effluent gases are then pumped out of the plasma-type effluent abatement system 226 by the vacuum pump 210. The vacuum pump 210 may be controlled by the process controller 206. Similar to as described above with reference to FIG. 1, the process controller 206, which may be a computer, special processor, etc., acts as an abatement controller. Additionally, the process controller may obtain an indication of NOₓ in the exhaust 216 from one or more optional sensors 222. The process controller 206 controls operations of the combustion-type effluent abatement system 214, as well as the plasma-type effluent abatement system. The combustion-type effluent abatement system 214 may abate the effluent gases by combusting them with a mixture of combustion gas (e.g., natural gas, propane, etc.) and air. The process controller 206 may control the combustion-type effluent abatement system 214 by selecting from several modes of operation similar to those described above with reference to FIG. 1, including a mode wherein the combustion-type effluent abatement system ceases combustion operations.

Referring again to FIG. 2A, the abated effluent gases may then flow to a scrubber 224, for example, or to an exhaust 216, if operations and regulatory requirements allow.

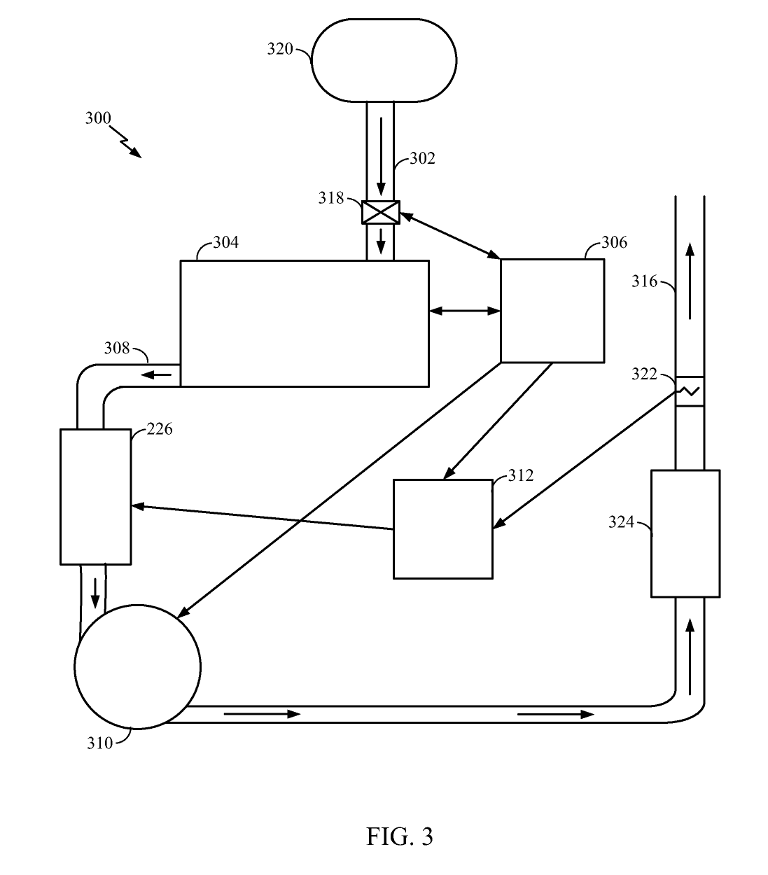

FIG. 3 is a schematic diagram of a processing system 300. The processing system 300 shown in FIG. 3 is similar to the processing system 200 shown in FIG. 2, but with the combustion-type effluent abatement system shown in FIG. 2 removed. The processing system 300 generally includes one or more process gas sources 320, one or more valves 318, a processing chamber 304, a process controller 306, a plasma-type effluent disposal or abatement subsystem 226, such as a ZFP2™ abatement system, available from Applied Materials™, a vacuum pump 310, an abatement controller 312, an optional scrubber 324, one or more optional exhaust gas sensors 322, and an exhaust 316. The process controller 306 and the abatement controller 312 may be the same controller, in some embodiments of the present disclosure.

Referring to FIG. 3, process gases are supplied from a process gas source 320 (e.g., a storage tank or pipeline) via an inlet 302 to the processing chamber 304. The supply of process gases is controlled and monitored by the process controller 306 which may control, for example, one or more valves 318. The process controller 306 may comprise a computer, for example. The process controller 306 controls and monitors operations in the processing chamber 304. Effluent gases exit the processing chamber 304 via one or more outlets 308.

Still referring to FIG. 3, the effluent gases then flow to a plasma-type effluent abatement system 226. The plasma-type effluent abatement system 226 may abate the effluent gases by exposing them to a plasma. The plasma-type effluent abatement system 226 may generate a plasma to abate the effluent gases by various techniques, including radio frequency (RF), direct current (DC), or microwave (MW) based power discharge techniques. The plasma-type effluent abatement system 226 may operate in an “always-on” mode, operate in an operational mode selected by the abatement controller 312, or cease operations if the abatement controller 312 directs it to turn off. The abatement controller 312 selects operational modes for the plasma-type effluent abatement system based on process parameters obtained from the process controller 306 and/or an indication of NOₓ in the exhaust 316 of the effluent abatement system. The abatement controller 312 may be referred to as a nitrogen oxide reducing system, when configured as described herein.

Continuing with reference to FIG. 3, the effluent gases are then pumped out of the plasma-type effluent abatement system 226 by the vacuum pump 310. The vacuum pump 310 may be controlled by the process controller 106. The abated effluent gases may then flow to a scrubber 324, for example, or directly to an exhaust 316, if operations and regulatory requirements allow.

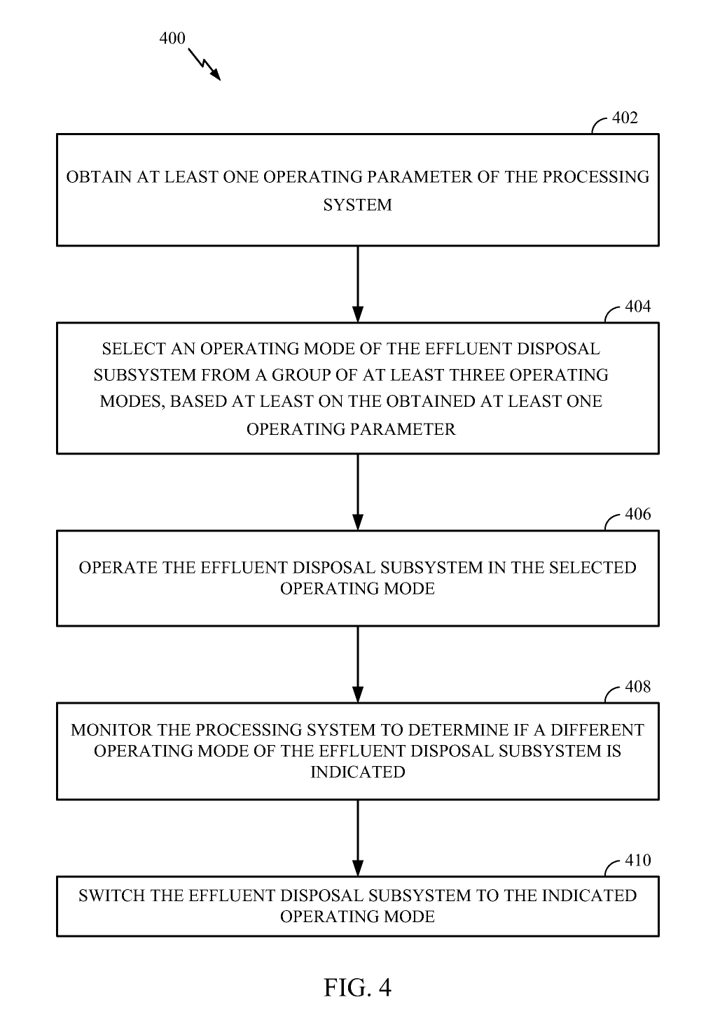

FIG. 4 sets forth an exemplary operation 400 to reduce NOₓ produced by a processing system 100 or 300 that may be performed, for example, by an abatement controller 112, 312, in accordance with certain aspects of the present disclosure. As illustrated, at 402, the abatement controller 112, 312 obtains at least one operating parameter of the processing system. The at least one operating parameter may include a process gas composition, process gas flow rate, vacuum pump pumping rate, etc. Operations continue at 404 by the abatement controller 112, 312 selecting an operating mode of the effluent abatement system from a group of at least three operating modes, based at least on the obtained at least one operating parameter. The three operating modes may include, for example, a high capacity mode selected if the process gas flow rate into the processing chamber 104 is high, a low capacity mode selected if the process gas flow rate into the processing chamber 104 is low, and an idle mode selected if the processing chamber 104 is idle. At 406, the abatement controller 112, 312 operates the combustion-type effluent abatement system 114 or the plasma-type effluent abatement system 226 in the selected operating mode. Operations continue at 408 with the abatement controller 112, 312 monitoring the processing system to determine if a different operating mode of the effluent abatement system 114 or 226 is indicated. For example, if the processing chamber 104, 304 finishes processing a substrate and stops the flow of process gases, the abatement controller 112, 312 detects this at 408 and determines that the effluent abatement system 114 or 226 should switch to a low capacity mode. At 410, the abatement controller 112, 312 switches the effluent abatement system 114 or 226 to the indicated operating mode.

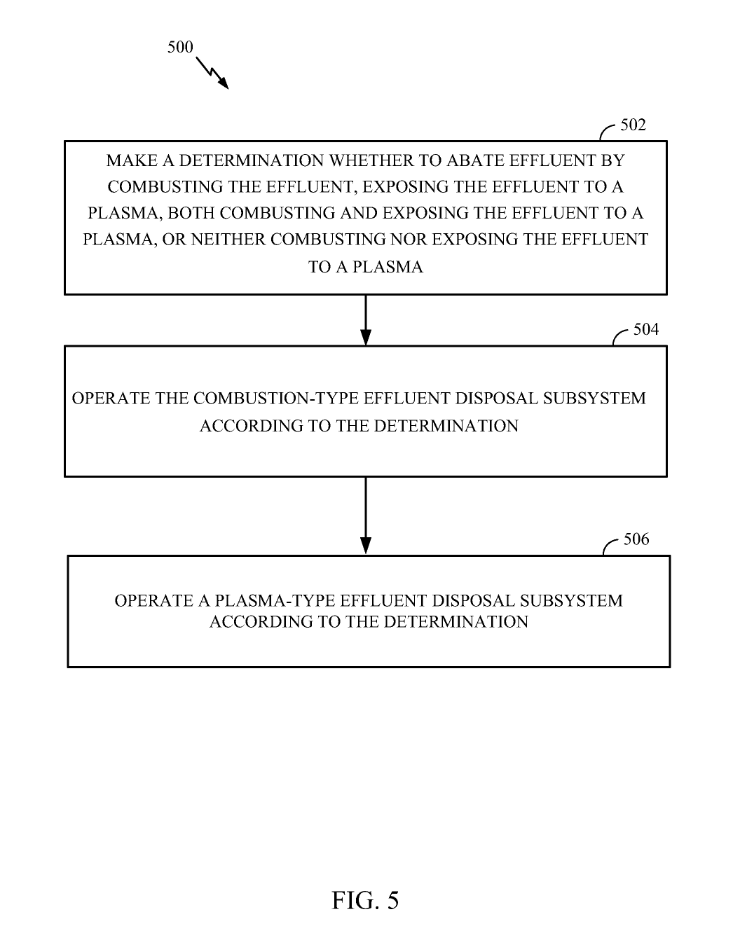

FIG. 5 illustrates an exemplary operation 500 to reduce NOₓ produced by a processing system 200 including a combustion-type effluent abatement system 214 that may be performed, for example, by an abatement controller 212, in accordance with certain aspects of the present disclosure. At 502, the abatement controller 212 makes a determination whether to abate effluent by combusting the effluent, exposing the effluent to a plasma, both combusting and exposing the effluent to a plasma, or neither combusting nor exposing the effluent to a plasma. For example, at 502 the abatement controller 212 may determine that the effluent does not require abatement by combustion, but does require abatement by exposing to a plasma. At 504, the abatement controller 212 controls the combustion-type effluent abatement system 214 to operate according to the determination. For example, if the abatement controller determines that the effluent does not require abatement by combustion, then at 504 the abatement controller 212 may operate the combustion-type effluent abatement system 214 in an idle mode. Operations may continue at 506, wherein the abatement controller 212 controls a plasma-type effluent abatement system 226 to operate according to the determination. For example, if the abatement controller determines that effluent flowing at a high rate requires abatement by exposure to a plasma, the abatement controller 212 may operate the plasma-type effluent abatement system 226 in a high capacity mode.

The abatement controller 112, 212, 312, can operate under the control of a computer program stored on a hard disk drive of a computer. For example, the computer program can dictate the operation timing, mixture of gases, operating temperature, and RF power levels of effluent abatement systems 114 and 226. The interface between a user and the abatement controller can be made via a touchscreen (not shown).

A variety of operating modes can be implemented using a computer program product that runs on, for example, the abatement controller 112, 212, 312. The computer program code can be written in any conventional computer readable programming language such as, for example, 68000 assembly language, C, C++, or Pascal. Suitable program code can be entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled library routines. To execute the linked compiled object code, the system user invokes the object code, causing the computer system to load the code in memory, from which the CPU reads and executes the code to perform the tasks identified in the program.

Unless otherwise indicated, all numbers expressing quantities of ingredients, properties, reaction conditions, and so forth, used in the specification and claims are to be understood as approximations. These approximations are based on the desired properties sought to be obtained by the present invention, and the error of measurement, and should at least be construed in light of the number of reported significant digits and by applying ordinary rounding techniques. Further, any of the quantities expressed herein, including temperature, pressure, spacing, molar ratios, flow rates, and so on, can be further optimized to achieve the desired reduction in the production of NOₓ in the processing system and effluent abatement system.

While the foregoing is directed to embodiments of the present invention, other and further embodiments of the invention may be devised without departing from the basic scope thereof, and the scope thereof is determined by the claims that follow.

1. A method for reducing nitrogen oxides (NOₓ) produced by a processing system including an effluent abatement system, comprising:
obtaining at least one operating parameter of the processing system; and
selecting an operating mode of the effluent abatement system from a group of at least three operating modes, based at least on the obtained at least one operating parameter.

2. The method of claim 1, wherein the at least one operating parameter comprises a flow rate and composition of at least one gas supplied to the processing system.

3. The method of claim 1, wherein the at least one operating parameter comprises a temperature of a processing chamber.

4. The method of claim 1, further comprising:
obtaining an indication of NOₓ in an exhaust of the effluent abatement system; and
selecting the operating mode of the effluent abatement system based further on the obtained indication.

5. A method for reducing nitrogen oxides (NOₓ) produced by a processing system including a combustion-type effluent abatement system, comprising:
making a determination whether to abate effluent by combusting the effluent, exposing the effluent to a plasma, both combusting and exposing the effluent to a plasma, or neither combusting nor exposing the effluent to a plasma;
operating the combustion-type effluent abatement system according to the determination; and
operating a plasma-type effluent abatement system according to the determination.

6. A system for reducing nitrogen oxides (NOₓ) produced by a processing system including an effluent abatement system, comprising a controller configured to:
obtain at least one operating parameter of the processing system; and
select an operating mode of the effluent abatement system from a group of at least three operating modes, based at least on the obtained at least one operating parameter.

7. The system of claim 6, wherein the at least one operating parameter comprises a flow rate and composition of at least one gas supplied to the processing system.

8. The system of claim 6, wherein the at least one operating parameter comprises a temperature of a processing chamber.

9. The system of claim 6, wherein the group of at least three operating modes includes a high capacity mode, a low capacity mode, and an idle mode.

10. The system of claim 9, wherein the controller is further configured to select the high capacity mode if an operating parameter cannot be obtained.

11. The system of claim 6, wherein the group of at least three operating modes includes at least one of a high combustion gas flow rate mode, a high combustion temperature mode, a low combustion gas flow rate mode, a low combustion temperature mode, a high combustion air flow rate mode, and a low combustion air flow rate mode.

12. The system of claim 6, wherein the controller is further configured to:
obtain an indication of NOₓ in an exhaust of the effluent abatement system; and
select the operating mode of the effluent abatement system based further on the obtained indication.

13. A system for reducing nitrogen oxides (NOₓ) produced by a processing system comprising:
a controller operable to make a determination whether to abate effluent by combusting the effluent, exposing the effluent to a plasma, both combusting and exposing the effluent to a plasma, or neither combusting nor exposing the effluent to a plasma; and
a controller operable to control operation of a combustion-type effluent abatement system and a plasma-type effluent abatement system according to the determination.

14. The system of claim 13, wherein the controller operable to make the determination is further operable to:
obtain at least one operating parameter of the processing system; and
make the determination based at least on the at least one operating parameter.

15. The system of claim 13, wherein the controller operable to make the determination is further operable to:
obtain an indication of NOₓ in an exhaust of the processing system; and
make the determination based at least on the obtained indication.
